(19) United States
(12) Patent Application Publication
(10) Pub. No.: US 2022/0154043 A1
(43) Pub. Date: May 19, 2022

(54) ADHESIVE COMPOSITION FOR DICING FILM, DICING FILM AND DICING DIE BOND FILM

(71) Applicant: LG CHEM, LTD., Seoul (KR)

(72) Inventors: Ji Ho HAN, Daejeon (KR); Da Ae KIM, Daejeon (KR); Kwang Joo LEE, Daejeon (KR); Mi JANG, Daejeon (KR); Bo Ra YEON, Daejeon (KR); Kwang Su SEO, Daejeon (KR); Mi Seon KIM, Daejeon (KR)

(73) Assignee: LG CHEM, LTD., Seoul (KR)

(21) Appl. No.: 17/496,917

(22) Filed: Oct. 8, 2021

(30) Foreign Application Priority Data
Nov. 18, 2020 (KR) 10-2020-0154199

(51) Int. Cl. C09J 4/06; C09J 7/25; C08F 2/50; C08F 220/28; C08F 220/18; C08F 220/20

(52) U.S. Cl. CPC C09J 4/06; C09J 7/255; C08F 2/50; H01L 21/6836; C08F 220/1808; C08F 220/20; C08F 220/282

(57) ABSTRACT

The present disclosure provides an adhesive composition for a dicing film, a dicing film, and a dicing die-bonding film, which have excellent pickup performance.

### CROSS-REFERENCE TO RELATED APPLICATION

This application claims the benefit of the filing date of Korean Patent Application No. 10-2020-0154199 filed with the Korean Intellectual Property Office on Nov. 18, 2020, the entire contents of which are incorporated herein by reference.

### 1. TECHNICAL FIELD

The present disclosure relates to an adhesive composition for a dicing film, a dicing film, and a dicing die-bonding film. Specifically, the present disclosure relates to an adhesive composition for a dicing film, a dicing film, and a dicing die-bonding film, which have excellent pickup performance.

### 2. BACKGROUND OF THE INVENTION

In general, semiconductor chip fabrication processes includes a process of forming a fine pattern on a wafer and a process of polishing and packaging the wafer to meet the specifications of a final device.

The packaging process includes: a wafer testing process of testing semiconductor chips for defects; a dicing process of dividing a wafer into individual chips by cutting; a die bonding process of attaching the separate chips to a mounting board of a circuit film or lead frame; a wire bonding process of connecting a chip pad provided on a semiconductor chip to a circuit pattern of the circuit film or lead frame via electrical connecting means such as a wire; a molding process of enclosing the outside with an encapsulating material in order to protect the internal circuit of the semiconductor chip and other parts; a trimming process of cutting a dam bar connecting leads; a forming process of bending the leads into a desired shape; and a final product testing process of testing a packaged product for defects.

In the dicing process, a wafer is cut to a predetermined size by means of a diamond wheel or the like. Before the dicing process, a dicing film is laminated on the backside of the wafer under suitable conditions in order to fix the wafer. In addition, a die bonding film (adhesive film) is used to attach diced individual chips to a circuit board. Through the dicing process, individual chips separated from each other are fabricated from the semiconductor wafer having a plurality of chips formed thereon. In a broad sense, the dicing process is a process of fabricating a plurality of individual chips separated from each other by grinding the backside of a semiconductor wafer and cutting the semiconductor wafer along a dicing line between the chips.

In addition, in a conventional cutting process, a problem arises in that the yield is lowered due to damage to chips. In order to solve this problem, a fabrication process including an expanding process after a process of cutting a semiconductor chip using a blade or modifying the cross-section of a semiconductor chip using a laser has been proposed. In this fabrication process, the cut or cross-section-modified semiconductor wafer is expanded, and a plurality of individual chips are picked up by irradiating a substrate film on the semiconductor wafer with UV light.

However, during the expanding process, a die lifting phenomenon occurs in which the periphery of the cut chip is lifted, and oxygen is trapped in the lifted portion. Thereafter, the radicals generated in the UV irradiation process react with the trapped oxygen to form peroxyl radicals, and thus an oxygen inhibition phenomenon occurs in which the film on the periphery of the chip does not react with UV light. The film surface on which the oxygen inhibition phenomenon has occurred remains highly adhesive, and a problem arises in that the adhesion between the films occurs when the chips are picked up, resulting in deterioration in the pickup property of the chips.

### BRIEF SUMMARY OF THE INVENTION

An object of the present disclosure is to provide an adhesive composition for a dicing film, a dicing film, and a dicing die-bonding film, which have excellent pickup performance even when lifting of chips occurs due to wafer thinning or even when the adhesive layer is exposed to oxygen due to the lifting.

However, the object to be achieved by the present disclosure is not limited to the above-mentioned object, and other objects not mentioned herein will be clearly understood by those skilled in the art from the following description.

According to one aspect of the present disclosure, there is provided an adhesive composition for a dicing film containing a (meth)acrylate copolymer obtained by copolymerization from a mixture containing: a first monomer represented by the following Formula 1; a second monomer that is a (meth)acrylate containing an alkyl group having 3 to 10 carbon atoms; and a third monomer that is a (meth)acrylate containing a hydroxyl group, wherein the first monomer is contained in an amount of 20 wt % to 40 wt % based on the total weight of the mixture:

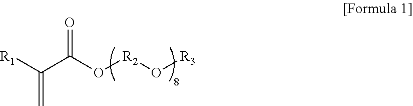

wherein: R₁ is hydrogen or a methyl group; R₂ is a methylene group, an ethylene group or a propylene group; R₃ is a substituted or unsubstituted alkyl group having 1 to 5 carbon atoms; and n is a natural number ranging from 1 to 10.

According to another aspect of the present disclosure, there is provided a dicing film including: a substrate film; and an adhesive layer including a cured product of the adhesive composition for a dicing film.

According to still another aspect of the present disclosure, there is provided a dicing die-bonding film including: the dicing film; and a die-bonding film.

### DETAILED DESCRIPTION OF THE INVENTION

The terms used in the specification and claims should not be interpreted as being limited to usual or dictionary meanings, but should be interpreted as having meanings and concepts in conformity with the technical spirit of the present disclosure, based on the principle that the inventors can appropriately define the meaning of the terms to describe their invention in the best manner. Accordingly, it should be understood that the embodiments described in the specification and the features thereof are merely the most preferable examples, but not cover all the technical spirits of the present disclosure, and thus there may be various equivalents and modifications capable of replacing them at the time of filing this application.

Throughout the present specification, it is to be understood that when any part is referred to as “including” any component, it does not exclude other components, but may further include other components, unless otherwise specified.

Throughout the present specification, when any member is referred to as being “on” another member, it not only refers to a case where any member is in contact with another member, but also a case where a third member exists between the two members.

Throughout the present specification, the unit “parts by weight” may refer to the ratio of weight between components.

Throughout this specification, the term “(meth)acrylate” is meant to include acrylate and methacrylate.

Throughout the present specification, the “weight-average molecular weight” and “number-average molecular weight” of any compound may be calculated using the molecular weight and molecular weight distribution of the compound. Specifically, the molecular weight and molecular weight distribution of the compound may be obtained by: placing tetrahydrofuran (THF) and the compound in a 1-ml glass vial to prepare a test sample in which the concentration of the compound is 1 wt %; filtering a standard sample (polystyrene) and the test sample through a filter (pore size: 0.45 m); injecting each of the sample filtrates into a GPC injector; and comparing the elution time of the test sample with a calibration curve of the standard sample. At this time, Infinity II 1260 (Agilent Technologies, Inc.) may be used as a measurement instrument, and the flow rate and the column temperature may be set at 1.00 mL/min and 40.0° C., respectively.

Throughout the present specification, “glass transition temperature (Tg)” may be measured using differential scanning calorimetry (DSC). Specifically, the glass transition temperature may be measured using a differential scanning calorimeter (DSC, DSCQ2000, TA Instrument Korea) by performing a two-cycle experiment while heating a sample in the temperature range of −60° C. to 150° C. at a heating rate of 5° C./min, and then measuring the midpoint of the DSC curve plotted from points having thermal changes.

Hereinafter, the present disclosure will be described in more detail.

According to one embodiment of the present disclosure, there is provided an adhesive composition for a dicing film containing a (meth)acrylate copolymer obtained by copolymerization from a mixture containing: a first monomer represented by the following Formula 1; a second monomer that is a (meth)acrylate containing an alkyl group having 3 to 10 carbon atoms; and a third monomer that is a (meth)acrylate containing a hydroxyl group, wherein the first monomer is contained in an amount of 20 wt % to 40 wt % based on the total weight of the mixture:

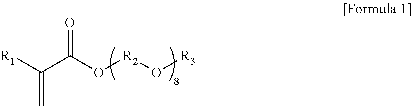

wherein: R₁ is hydrogen or a methyl group; R₂ is a methylene group, an ethylene group or a propylene group; R₃ is a substituted or unsubstituted alkyl group having 1 to 5 carbon atoms; and n is a natural number ranging from 1 to 10.

The adhesive composition for a dicing film according to one embodiment of the present disclosure may improve the pickup performance of the dicing film, because the adhesiveness thereof may be effectively decreased even when the adhesive composition is irradiated with UV light under oxygen-exposed conditions. Specifically, the (meth)acrylate copolymer contained in the adhesive composition for a dicing film is one obtained by copolymerization from the mixture containing the first monomer represented by Formula 1. Thus, even when the adhesive composition is irradiated with UV light under oxygen-exposed conditions, the first monomer represented by Formula 1 may reduce peroxyl radicals generated by the contact reaction between radicals and oxygen, thereby suppressing the oxygen inhibition phenomenon. This suggests that the adhesive composition may have excellent pickup performance, because the adhesiveness thereof is effectively decreased by UV irradiation even under oxygen-reduced environments.

According to one embodiment of the present disclosure, the (meth) acrylate copolymer may be obtained by copolymerization from a mixture containing a first monomer represented by Formula 1, a second monomer that is a (meth) acrylate containing an alkyl group having 3 to 10 carbon atoms, and a third monomer that is a (meth)acrylate containing a hydroxyl group.

According to one embodiment of the present disclosure, a method of obtaining the (meth)acrylate copolymer by copolymerization from the mixture is not particularly limited, and may be, for example, a method such as solution polymerization, bulk polymerization or emulsion polymerization.

According to one embodiment of the present disclosure, if necessary, the mixture may further contain at least one additive selected from a initiator, a solvent, and a chain transfer agent in addition to the first to third monomers.

According to one embodiment of the present disclosure, the (meth)acrylate copolymer may have a weight-average molecular weight of 300,000 to 1,000,000. When the (meth)acrylate copolymer has a weight-average molecular weight within the above range, the (meth)acrylate copolymer may exhibit an excellent adhesive effect. If the weight-average molecular weight is lower than the lower limit of the above range, residue may remain after film removal, and if the weight-average molecular weight is higher than the upper limit of the above range, a phenomenon may occur in which the uniformity of an adhesive coating film formed of the adhesive composition decreases.

According to one embodiment of the present disclosure, the first monomer may have a structure represented by the following Formula 1. For example, the first monomer may include at least one of 2-(2-ethoxyethoxy)ethyl (meth)acrylate, 2-(2-methoxyethoxy)ethyl (meth)acrylate, and 2-[2-(2-methoxyethoxy)ethoxy]ethyl (meth)acrylate. Preferably, the first monomer may include 2-(2-ethoxyethoxy)ethyl (meth)acrylate.

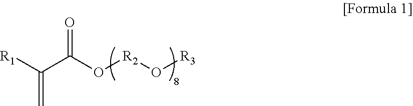

wherein: R₁ is hydrogen or a methyl group; R₂ is a methylene group, an ethylene group or a propylene group; R₃ is a substituted or unsubstituted alkyl group having 1 to 5 carbon atoms; and n is a natural number ranging from 1 to 10.

The first monomer has the property of re-initiating hydrogen extraction and radical reaction through oxidation, constitutes the first repeating unit of the (meth)acrylate copolymer, and has the effect of suppressing the oxygen inhibition phenomenon. Thus, when the adhesive composition is irradiated with UV light under oxygen-exposed conditions, the first monomer may effectively decrease the adhesiveness of the adhesive composition, thereby enabling the dicing film to ensure excellent pickup performance.

According to an embodiment of the present disclosure, the first monomer may be contained in an amount of 20 wt % to 40 wt %, 25 wt % to 40 wt %, 20 wt % to 35 wt %, 25 wt % to 35 wt %, or 25 wt % to 30 wt %, based on the total weight of the mixture. When the first monomer is contained in an amount within the above range, it may effectively improve pickup performance by having appropriate adhesive properties after UV irradiation, and the die lift phenomenon may not occur.

According to one embodiment of the present disclosure, the second monomer is a (meth)acrylate containing an alkyl group having 3 to 10 carbon atoms. For example, the second monomer may include at least one of pentyl (meth)acrylate, n-butyl (meth)acrylate, hexyl (meth)acrylate, n-octyl (meth)acrylate, isooctyl (meth)acrylate, 2-ethylhexyl (meth)acrylate, and decyl (meth)acrylate. Preferably, the second monomer may include 2-ethylhexyl (meth)acrylate.

As the second monomer may be contained in the (meth)acrylate copolymer, it is possible to achieve the basic physical properties of an adhesive layer formed of the adhesive composition containing the (meth)acrylate copolymer.

According to one embodiment of the present disclosure, the second monomer may be contained in an amount of 40 wt % to 70 wt %, 40 wt % to 60 wt %, 40 wt % to 50 wt %, or 50 wt % to 60 wt %, based on the total weight of the mixture. When the second monomer is contained in an amount within the above range, it may ensure an appropriate level of glass transition temperature, thus ensuring appropriate adhesiveness.

According to one embodiment of the present disclosure, the third monomer is a (meth)acrylate containing a hydroxyl group. For example, the third monomer may include at least one of 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 2-hydroxyethylene glycol (meth)acrylate, and 2-hydroxypropylene glycol (meth)acrylate. Preferably, the third monomer may include 2-hydroxyethyl (meth)acrylate.

As the third monomer contains a hydroxyl group, the (meth)acrylate copolymer may impart adhesiveness that can be variable by a curing reaction so that it is possible to form an adhesive film. Accordingly, the adhesive film may be easily removed while the adhesive layer formed of the adhesive composition does not leave residue.

According to one embodiment of the present disclosure, the third monomer may be contained in an amount of 5 wt % to 30 wt %, 5 wt % to 20 wt %, 10 wt % to 20 wt %, or 20 wt % to 30 wt %, based on the total weight of the mixture. When the third monomer is contained in an amount within the above range, no residue remains after film removal, and the adhesive film may be easily removed when the removal thereof is required.

According to one embodiment of the present disclosure, the (meth)acrylate copolymer may include: a first repeating unit derived from the first monomer; a second repeating unit derived from the second monomer; a third repeating unit derived from the third monomer; and a fourth repeating unit in which the hydroxyl group of the repeating unit derived from the third monomer forms a urethane bond with a fourth monomer that is a (meth)acrylate containing an isocyanate group. Specifically, some of the hydroxyl groups contained in the repeating unit derived from the third monomer do not react and thus may correspond to the third repeating unit, and some of the hydroxyl groups form urethane bonds with the fourth monomer, which is a (meth)acrylate containing an isocyanate group, and thus may correspond to the fourth repeating unit.

According to one embodiment of the present disclosure, the (meth)acrylate copolymer may be produced by a method including steps of: prepolymerizing the mixture to form a prepolymer; and mixing and reacting the prepolymer with a fourth monomer to form a fourth repeating unit.

According to one embodiment of the present disclosure, the fourth monomer may be a (meth)acrylate containing an isocyanate group.

The fourth monomer may react with and be bonded to the hydroxyl group of the third repeating unit derived from the third monomer contained in the prepolymer. In particular, the fourth monomer may be bonded to the hydroxyl group via a urethane bond formed between the isocyanate group contained in the fourth monomer and the hydroxyl group. When the fourth repeating unit is formed by the above-described reaction, no residue will remain after film removal, and the fourth monomer may have curing reactivity with UV light.

According to one embodiment of the present disclosure, the fourth monomer may be mixed in an amount of 10 to 20 parts by weight, or 10 to 15 parts by weight, based on 100 parts by weight of the prepolymer. When the fourth monomer is mixed in an amount within the above range, chip pickup after UV irradiation may be effectively achieved.

According to one embodiment of the present disclosure, the molar ratio of the third repeating unit to the fourth repeating unit may be 4:6 to 9:1, 5:5 to 8:2, or 6:4 to 7:3. When the third repeating unit and the fourth repeating unit are contained at a molar ratio within the above range, there may be an effect of significantly reducing the adhesiveness of the adhesive composition after UV irradiation.

According to one embodiment of the present disclosure, the fourth monomer may include at least one of (meth)acryloyl isocyanate, (meth)acryloyloxy isocyanate, (meth)acryloyloxymethyl isocyanate, 2-(meth)acryloyloxyethyl isocyanate, 3-(meth)acryloyloxypropyl isocyanate, and 4-(meth)acryloyloxybutyl isocyanate. Preferably, the fourth monomer may include 2-(meth)acryloyloxy ethyl isocyanate.

According to one embodiment of the present disclosure, the adhesive composition may further contain at least one additive selected from among a photoinitiator, a curing agent, and a solvent, if necessary.

According to one embodiment of the present disclosure, specific examples of the photoinitiator are not limited, and a conventionally known photoinitiator may be used. For example, the photoinitiator may include at least one of benzoin and its alkyl ethers, acetophenones, anthraquinones, thioxanthones, ketals, benzophenones, α-aminoacetophenones, acylphosphine oxides, and oxime esters.

According to one embodiment of the present disclosure, the photoinitiator may be contained in the mixture in an amount of 1 to 10 parts by weight, 1 to 5 parts by weight, or 1 to 3 parts by weight, based on 100 parts by weight of the (meth)acrylate copolymer. When the photoinitiator is used in an amount within the above range, it may initiate a photocrosslinking reaction when the adhesive layer of the dicing film is irradiated with UV light, thereby reducing the adhesiveness of the adhesive layer, resulting in improvement of the pickup performance of the film.

According to one embodiment of the present disclosure, the curing agent may include at least one of an isocyanate-based compound, an aziridine-based compound, an epoxy-based compound, and a metal chelate-based compound. In particular, the curing agent may include a polyfunctional isocyanate-based compound among isocyanate-based compounds.

According to one embodiment of the present disclosure, the curing agent may be contained in the mixture in an amount of 1 to 10 parts by weight, 1 to 5 parts by weight, or 1 to 3 parts by weight, based on 100 parts by weight of the (meth)acrylate copolymer. When the curing agent is used in an amount within the above range, it may adjust the curing rate of the adhesive composition so that the composition may be easily formed into the adhesive layer.

According to one embodiment of the present disclosure, specific examples of the solvent are not limited, and a conventionally known solvent may be used. For example, the solvent include at least one of ethyl acetate, butyl acetate, and methyl ethyl ketone.

According to one embodiment of the present disclosure, the solvent may be contained in the mixture in an amount of 30 parts by weight to 300 parts by weight, 50 parts by weight to 200 parts by weight, or 100 parts by weight to 150 parts by weight, based on 100 parts by weight of the (meth)acrylate copolymer. When the solvent is used in an amount within the above range, it may improve the processability of the adhesive composition while controlling the viscosity of the adhesive composition to an appropriate level.

According to another embodiment of the present disclosure, there is provided a dicing film including: a substrate film; and an adhesive layer including a cured product of the adhesive composition for a dicing film.

According to still another embodiment of the present disclosure, there is provided a dicing die-bonding film including: the dicing film; and a die-bonding film.

The dicing film and the dicing die-bonding film may have excellent pickup performance, because they may suppress the die lift phenomenon in the dicing process, and the adhesiveness thereof may be decreased even when they are irradiated with UV light under oxygen-exposed conditions.

The dicing die-bonding film according to one embodiment of the present disclosure may satisfy the following Equation 1:

(A−B)/A*100>40 [Equation 1]

wherein A is the peeling force between the dicing film and the die-bonding film, and B is the peeling force between the dicing film and the die-bonding film after the dicing die-bonding film is irradiated with UV light at a dose of 400 mJ/cm² under oxygen-exposed conditions.

As the dicing die-bonding film satisfies Equation 1 above, the adhesiveness of the dicing die-bonding film may be effectively decreased after UV irradiation, and thus a pickup process may be smoothly performed without damage to a semiconductor chip during the process.

Hereinafter, the present disclosure will be described in detail with reference to examples. However, the examples according to the present disclosure may be modified into various different forms, and the scope of the present disclosure is not interpreted as being limited to the examples described below. The examples of the present specification are provided to more completely explain the present disclosure to those skilled in the art.

### Example 1

Production of Adhesive Composition

20 parts by weight of 2-(2-ethoxyethoxy)ethyl acrylate (EOEOEA), 60 parts by weight of 2-ethylhexyl acrylate (EHA), 20 parts by weight of hydroxyethyl acrylate (HEA), 285 parts by weight of ethyl acetate as a solvent, and 0.003 parts by weight of AIBN as a initiator, were mixed together to prepare a monomer mixture. Next, the inside of the reactor was purged with nitrogen, and then the monomer mixture was stirred sufficiently at 30° C. for 30 minutes and then warmed to a temperature of 60° C. At this temperature, the mixture was stirred for 6 hours, thus producing a prepolymer. Next, 100 parts by weight of the produced prepolymer was stirred while a mixture solution of 16 parts by weight of methacryloyloxyethyl isocyanate (MOI) and 0.016 parts by weight of a Sn catalyst was added thereto at a rate of to 1 mL/min, thus producing an acrylate copolymer. At this time, in the acrylate copolymer, the molar ratio of a third repeating unit, which is a repeating unit derived from hydroxyethyl acrylate, to a fourth repeating unit in which the hydroxyl group of the repeating unit derived from hydroxyethyl acrylate forms a urethane bond with methacryloyloxyethyl isocyanate that is a photocurable monomer, was about 6:4.

3 parts by weight of TDI-based isocyanate as a polyfunctional crosslinking agent and 3 parts by weight of Omnirad 184 as a photoinitiator were added to and mixed with 100 parts by weight of the produced acrylate copolymer, thus producing an adhesive composition.

Production of Dicing Film

The produced adhesive composition was applied to a release-treated polyethylene terephthalate (PET) substrate having a thickness of 38 μm, and dried at 110° C. for 3 minutes to form an adhesive layer having a thickness of 10 m. The formed adhesive layer was laminated to a polyolefin substrate having a thickness of 90 m and aged at 40° C., thus producing a dicing film having a structure consisting of PET substrate-adhesive layer-polyolefin substrate.

Production of Die-Bonding Film

A composition consisting of 90 g of high molecular weight acrylic resin (Tg: 20° C.; weight-average molecular weight: 850,000), 30 g of epoxy resin (novolak type epoxy resin; softening point: 94° C.), 20 g of phenolic resin (phenol novolac resin; softening point: 94° C.) as a curing agent for the epoxy resin, 0.1 g of a medium-temperature-initiation curing accelerator (2-methylimidazole), 0.5 g of a high-temperature-initiation curing accelerator (2-phenyl-4-methyl-imidazole), and 20 g of silica (average particle diameter: 75 nm) as a filler was mixed with methyl ethyl ketone and stirred.

The mixture was applied onto a releasable substrate, and dried at 110° C. for 3 minutes, thus producing a die-bonding film having an adhesive layer thickness of 20 m.

Production of Dicing Die-Bonding Film

The adhesive layer of the die-bonding film cut in a circle was transferred onto the PET substrate-peeled adhesive layer surface by lamination under a condition of 5 kgf/cm² so that they were in contact with each other, thus producing a dicing die-bonding film.

### Examples 2 and 3 and Comparative Examples 1 to 3

Dicing die-bonding films were produced in the same manner as in Example 1, except that adhesive compositions having the compositions shown in Table 1 below were produced.

TABLE 1

| | | | | | Crosslinking | Photo- |
|---|---|---|---|---|---|---|
| | EOEOEA | HEA | EHA | MOI | agent | initiator |
| Example 1 | 20 | 20 | 60 | 16 | 3 | 3 |
| Example 2 | 40 | 20 | 40 | 16 | 3 | 3 |
| Example 3 | 30 | 20 | 50 | 16 | 3 | 3 |
| Comparative | 0 | 20 | 80 | 16 | 3 | 3 |
| Example 1 | | | | | | |
| Comparative | 10 | 20 | 70 | 16 | 3 | 3 |
| Example 2 | | | | | | |
| Comparative | 60 | 20 | 20 | 16 | 3 | 3 |
| Example 3 | | | | | | |

### Experimental Example 1: Evaluation of Change in Adhesiveness

For each of the dicing die-bonding films produced in Examples 1 to 3 and Comparative Examples 1 to 3, the interfacial adhesive force between the adhesive layer of the dicing film and the adhesive layer of the die-bonding film was measured. Specifically, the interfacial adhesive force was measured using a texture analyzer at a peeling angle of 180° and defined as the peeling force before UV irradiation, and the results of the measurement are shown in Table 2 below.

In addition, for each of the dicing die-bonding films produced in Examples 1 to 3 and Comparative Examples 1 to 3, the polyolefin substrate side was irradiated with UV light at a dose of 400 mJ/cm² under oxygen-exposed conditions, and then the interfacial adhesive force between the adhesive layer of the dicing film and the adhesive layer of the die-bonding film was measured under the same conditions as described above and defined as the peeling force after UV irradiation under oxygen-exposed conditions, and the results of the measurement are shown in Table 2 below.

In addition, for each of the dicing die-bonding films produced in Examples 1 to 3 and Comparative Examples 1 to 3, the polyolefin substrate side was irradiated with UV light at a dose of 400 mJ/cm² under non-oxygen-exposed conditions, and then the interfacial adhesive force between the adhesive layer of the dicing film and the adhesive layer of the die-bonding film was measured under the same conditions as described above and defined as the peeling force after UV irradiation under non-oxygen-exposed conditions, and the results of the measurement are shown in Table 2 below.

From the peeling force before UV irradiation and the peeling force after UV irradiation under oxygen-exposed conditions, measured as described above, an adhesiveness reduction rate was calculated using the following Equation 2:

Adhesiveness reduction rate (%)=(A−B)/A*100 [Equation 2]

wherein A is the peeling force before UV irradiation, and B is the peeling force after UV irradiation under oxygen-exposed conditions.

### Experimental Example 2: Evaluation of Die Lift Occurrence

Each of the dicing die-bonding films produced in Examples 1 to 3 and Comparative Examples 1 to 3 was mounted on a mirror wafer (12 inches, 35 μm thickness), which was divided into individual chips, at a temperature of 70° C., and then the die-bonding film was divided through an expanding process at a low temperature of −15° C. under the conditions described below. Next, expanding at room temperature was performed under the following conditions to ensure the chip gap, and then the die-bonding film was irradiated with UV light at a dose of 150 mJ/cm². Thereafter, measurement was performed on the length of the area where the lifting phenomenon occurred at the interface between the adhesive layer of the dicing film and the die-bonding film in the room-temperature expanding process.

[Expanding Process Conditions]
Apparatus used: DDS-2300 (DISCO)
Cool expansion amount height parameter: 13 mm
Room-temperature expansion amount height parameter: 13 mm

### Experimental Example 3: Evaluation of Pickup Performance

Each of the dicing die-bonding films produced in Examples 1 to 3 and Comparative Examples 1 to 3 was mounted on a mirror wafer (12 inches, 35 μm thickness), which was divided into individual chips, at a temperature of 70° C., and then the die-bonding film was divided through an expanding process at a low temperature of −15° C. Next, expanding at room temperature was performed to ensure the chip gap, and then the die-bonding film was irradiated with UV light at a dose of 150 mJ/cm², thus preparing samples for evaluation of pickup performance.

Evaluation of pickup performance of the prepared samples was performed under the following pickup conditions, and the results of the evaluation are shown in Table 2 below.

[Pickup Conditions]
Apparatus: SPA-400 (SHINKAWA)
Expanding height: 3.5 mm
Number of needles: 20
Needle plunge up height: 0.2 mm
Needle plunge up speed: 10 mm/s

Specifically, the pickup performance was evaluated by measuring the number of successfully picked up chips among 100 chips used during evaluation and calculating the success rate (%) of pickup.

TABLE 2

| | | Peeling force (gf/in) | | | Length | |
|---|---|---|---|---|---|---|
| | | after UV irradiation | | | (μm) of | |
| | Peeling force | Oxygen- | Non-oxygen- | Adhesiveness | area where | Pickup |
| | (gf/in) before | exposed | exposed | reduction rate | die lift | success |
| | UV irradiation | conditions | conditions | (%) | occurred | rate (%) |
| Example 1 | 550 | 325 | 11.0 | 41 | 0 | 100 |
| Example 2 | 410 | 231 | 14.7 | 44 | 0 | 100 |
| Example 3 | 510 | 301 | 12.1 | 41 | 0 | 100 |
| Comparative | 650 | 440 | 9.9 | 32 | 200 | 40 |
| Example 1 | | | | | | |
| Comparative | 560 | 350 | 10.1 | 38 | 120 | 80 |
| Example 2 | | | | | | |
| Comparative | 400 | 203 | 16.7 | 49 | 0 | 60 |
| Example 3 | | | | | | |

As shown in Table 2 above, it can be confirmed that the dicing die-bonding film according to Example 1 had an appropriate adhesiveness reduction rate after UV irradiation under oxygen-exposed conditions, had a low adhesiveness value after UV irradiation under non-oxygen-exposed conditions, had little or no die lift-occurred area, and corresponded to a pickup success rate of 100%, suggesting that the pickup performance thereof was excellent.

On the other hand, it can be confirmed that, in case of the dicing die-bonding film according to Comparative Example 1, since the (meth)acrylate copolymer did not contain a repeating unit derived from 2-(2-ethoxyethoxy)ethyl acrylate, the adhesiveness reduction rate was insufficient, die lift occurred over a wide area, and the pickup success rate was only 40%.

In addition, it can be confirmed that, in the case of Comparative Example 2 in which a small amount of 2-(2-ethoxyethoxy)ethyl acrylate was used, the adhesiveness reduction rate was also insufficient, die lift occurred, and the pickup success rate was only 80%. Furthermore, it can be confirmed that, in the case of Comparative Example 3 in which an excessive amount of 2-(2-ethoxyethoxy)ethyl acrylate was used, the peeling force after UV irradiation under non-oxygen-exposed conditions was high, and thus the pickup success rate was low.

As described above, the adhesive composition for a dicing film according to one embodiment of the present disclosure may improve the pickup performance of the dicing film, because the adhesiveness thereof is effectively decreased even when it is irradiated with UV light under oxygen-exposed conditions.

The dicing film according to another embodiment of the present disclosure may have excellent pickup performance, because it includes the adhesive composition for a dicing film.

The dicing die-boding film according to still another embodiment of the present disclosure may have excellent pickup performance, because the phenomenon of lifting between the dicing film and the die-bonding film thereof is suppressed.

The effects of the present disclosure are not limited to the above-described effects, and effects which are not mentioned herein will be clearly understood by those skilled in the art from the present specification.

Although the present disclosure has been described above by way of limited embodiments, the present disclosure is not limited thereto. It should be understood that the present disclosure can be variously changed and modified by those skilled in the art without departing from the technical sprit of the present disclosure and the range of equivalents to the appended claims.

1. An adhesive composition for a dicing film, comprising a (meth)acrylate copolymer obtained by copolymerization from a mixture containing: a first monomer represented by the following Formula 1; a second monomer that is a (meth)acrylate containing an alkyl group having 3 to 10 carbon atoms; and a third monomer that is a (meth)acrylate containing a hydroxyl group,
wherein the first monomer is contained in an amount of 20 wt % to 40 wt % based on the total weight of the mixture: 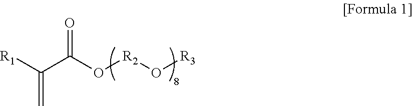
wherein:
R₁ is hydrogen or a methyl group;
R₂ is a methylene group, an ethylene group or a propylene group;
R₃ is a substituted or unsubstituted alkyl group having 1 to 5 carbon atoms; and
n is an integer ranging from 1 to 10.

2. The adhesive composition of claim 1, wherein the first monomer comprises at least one of 2-(2-ethoxyethoxy)ethyl (meth)acrylate, 2-(2-methoxyethoxy)ethyl (meth)acrylate, and 2-[2-(2-methoxyethoxy)ethoxy]ethyl (meth)acrylate.

3. The adhesive composition of claim 1, wherein the second monomer is contained in an amount of 40 wt % to 70 wt % based on the total weight of the mixture.

4. The adhesive composition of claim 1, wherein the second monomer comprises at least one of pentyl (meth)acrylate, n-butyl (meth)acrylate, hexyl (meth)acrylate, n-octyl (meth)acrylate, isooctyl (meth)acrylate, 2-ethylhexyl (meth)acrylate, and decyl (meth)acrylate.

5. The adhesive composition of claim 1, wherein the third monomer is contained in an amount of 5 wt % to 30 wt % based on the total weight of the mixture.

6. The adhesive composition of claim 1, wherein the third monomer comprises at least one of 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 2-hydroxyethylene glycol (meth)acrylate, and 2-hydroxypropylene glycol (meth)acrylate.

7. The adhesive composition of claim 1, wherein the (meth)acrylate copolymer comprises: a first repeating unit derived from the first monomer; a second repeating unit derived from the second monomer; a third repeating unit derived from the third monomer; and a fourth repeating unit in which a hydroxyl group of a repeating unit derived from the third monomer forms a urethane bond with a fourth monomer that is a (meth)acrylate containing an isocyanate group.

8. The adhesive composition of claim 7, wherein a molar ratio of the third repeating unit to the fourth repeating unit is 4:6 to 9:1.

9. The adhesive composition of claim 7, wherein the fourth monomer comprises at least one of (meth)acryloyl isocyanate, (meth)acryloyloxy isocyanate, (meth)acryloyloxymethyl isocyanate, 2-(meth)acryloyloxyethyl isocyanate, 3-(meth)acryloyloxypropyl isocyanate, and 4-(meth)acryloyloxybutyl isocyanate.

10. The adhesive composition of claim 1, wherein the (meth)acrylate copolymer has a weight-average molecular weight of 300,000 to 1,000,000.

11. The adhesive composition of claim 1, further comprising at least one additive selected from the group of a photoinitiator, a curing agent, and a solvent.

12. The adhesive composition of claim 11, wherein the photoinitiator is contained in an amount of 1 to 10 parts by weight based on 100 parts by weight of the (meth)acrylate copolymer.

13. The adhesive composition of claim 11, wherein the curing agent is contained in an amount of 1 to 10 parts by weight based on 100 parts by weight of the (meth)acrylate copolymer.

14. A dicing film comprising: a substrate film; and an adhesive layer comprising a cured product of the adhesive composition for a dicing film according to claim 1.

15. A dicing die-bonding film comprising: the dicing film comprising a substrate film, and an adhesive layer comprising a cured product of the adhesive composition for a dicing film according to claim 1; and a die-bonding film.

16. The dicing die-bonding film of claim 15, which satisfies the following Equation 1:
(A−B)/A*100>40 [Equation 1]
wherein
A is an initial peeling force between the dicing film and the die-bonding film, and
B is a peeling force between the dicing film and the die-bonding film after the dicing die-bonding film is irradiated with UV light at a dose of 400 mJ/cm² under oxygen-exposed conditions.
